(19) United States
(12) Patent Application Publication
(10) Pub. No.: US 2026/0107695 A1
(43) Pub. Date: Apr. 16, 2026

(54) QUANTUM DEVICE AND METHOD FOR PRODUCTION

(71) Applicant: COMMISSARIAT A L'ENERGIE ATOMIQUE ET AUX ENERGIES ALTERNATIVES, Paris (FR)

(72) Inventors: Valentin LABRACHERIE, Grenoble Cedex 09 (FR); Benoit BERTRAND, Grenoble Cedex 09 (FR); Heimanu NIEBOJEWSKI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/359,287

(22) Filed: Oct. 15, 2025

(30) Foreign Application Priority Data
Oct. 16, 2024 (FR) FR2411185

(51) Int. Cl. H10N 60/10; B82Y 10/00; H10N 60/01

(52) U.S. Cl. CPC H10N 60/128; H10N 60/01; H10N 60/11; B82Y 10/00

(57) ABSTRACT

A quantum device including an active zone extending along a longitudinal direction, and QD gates extending along a transverse direction, the QD gates being disposed on either side of the active zone, opposite one another, to control a quantum dot. The device includes transverse gates, each disposed on a pair of QD gates opposite one another, and separated from the QD gates and from the active zone by a gate dielectric. Each transverse gate is configured to control a transverse tunnel barrier between the QD gates.

### TECHNICAL FIELD

The present invention relates to the field of microelectronics and quantum electronics, in particular. It has, for example, a particularly advantageous application in producing quantum devices with quantum bits (or qubits), in particular devices with spin qubits.

### PRIOR ART

A quantum device with spin qubits typically comprises an active zone, for example, in the form of a nanowire or nanoribbon, where quantum dots are formed, and control gates associated with the quantum dots. The control gates typically make it possible to confine the elementary charges at the quantum dots, by forming an electrostatic potential well in the active zone.

Quantum devices with spin qubits are generally based on a quantum dot bilinear array architecture. Such an architecture makes it possible to both control and detect the state of these quantum dots.

A first line of the quantum dot array can be dedicated to the definition of qubits per se, while the second line of the array can be utilised to form quantum boxes serving to read the qubits. Subarrays of a few qubits can also be formed via this bilinear array architecture.

To ensure a reliable confinement at each quantum dot, control gates of the coupling by tunnel effect between quantum dots can be inserted. So-called longitudinal gates can be inserted between the quantum dots of one same line, to control the tunnel barriers between quantum dots along the longitudinal direction, i.e. along the quantum dot line. Document FR3120740A1 further discloses a “transverse” gate, making it possible to control the tunnel barriers between the quantum dots opposite the two lines of the bilinear array, along the transverse direction, i.e. perpendicularly to the quantum dot lines. This transverse gate extends longitudinally above the active zone and makes it possible to decouple the first and second quantum dot lines. This transverse decoupling is not optimal. This can prove to be problematic for controlling qubits, or for compensating for the local disorder.

There is therefore a need for novel quantum device architectures, enabling an improved control of qubits, and a better management of the coupling by tunnel effect.

An aim of the invention is to meet this need, and to overcome, at least partially, the disadvantages of known solutions.

In particular, an aim of the invention is a quantum device enabling a control of the improved transverse tunnel effect. Another aim of the invention is a method for producing such a device.

The other aims, features and advantages of the present invention will appear upon examining the description below, and the accompanying drawings. It is understood that other advantages can be incorporated.

### SUMMARY

To achieve this aim, according to an embodiment, a quantum device is provided, comprising successively, in a stack along a direction z:
a support layer,
an insulating layer, and
an active zone extending mainly along a so-called longitudinal direction,
first so-called QD control gates, extending mainly along a transverse direction with respect to the active zone, said first QD gates being disposed on either side of the active zone, opposite one another, each first QD gate being configured to control a potential well in the active zone, said potential well defining a quantum dot.

Advantageously, the device further comprises so-called transverse control gates, extending mainly along the transverse direction, each transverse gate being disposed on two first QD gates opposite one another forming a pair of first QD gates, and separated from said first QD gates and from the active zone by a first gate dielectric, each transverse gate being configured to control a transverse tunnel barrier between the first QD gates of said pair of first QD gates. Each transverse gate is typically associated with one single pair of QD gates.

Thus, the transverse tunnel barrier is controlled locally between two quantum dots of each pair of quantum dots opposite one another. The quantum dots arranged in line on one side of the active zone are individually decoupled from the quantum dots arranged opposite one another on the other side of the active zone. The transverse gates, which extend transversally above the first QD gates, advantageously enable a local and individual control of the coupling by tunnel effect between two quantum dots opposite one another, on either side of the active zone.

Another aspect of the invention relates to a method for producing such a device, comprising
A provision of a stack comprising, along the direction z, a support layer, an insulating layer, and a semiconductive layer,
A formation of a first lithography mask on the semiconductive layer, configured to define the active zone in the semiconductive layer,
An etching of the semiconductive layer, configured to form the active zone, said etching exposing the edges of said active zone,
A formation of a first dielectric barrier on each exposed edge of the active zone,
A deposition of a first gate layer on either side of the first lithography mask, against the first dielectric barrier bordering the active zone, said first gate layer being interrupted by the first lithography mask and intended to form the first QD gates on either side of the active zone,
A removal of the first lithography mask,
A continuous deposition of a first dielectric material on the first gate layer and above the active zone, intended to form the first gate dielectric,
A deposition of a second gate layer on the first dielectric material, said second gate layer being intended to form the transverse gates,
A formation of a second lithography mask on the second gate layer, configured to define the transverse gates and pairs of first QD gates under the transverse gates,
An etching along the direction z of the second gate layer, of the first dielectric material, and of the first gate layer, so as to form the transverse gates, the first gate dielectric and the pairs of first QD gates under each transverse gate, the transverse gates being self-aligned with the pairs of first QD gates that they surmount.

Advantageously, this method makes it possible to produce the transverse gates self-aligned with the first QD gates. Each pair of first QD gates opposite one another along the transverse direction is surmounted by a self-aligned transverse gate. The dimensions by width of the transverse gates are typically identical to the dimensions by width of the first QD gates that they surmount. This precise dimensional control makes it possible to improve the electrostatic control in the quantum device. The confinement of the charges and/or the decoupling of the charges between quantum dots is thus improved.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIG. 1A schematically illustrates, in a transverse cross-section, a quantum device, according to a first embodiment of the present invention.

FIG. 1B schematically illustrates, in a transverse cross-section, a quantum device, according to a variant of the first embodiment of the present invention.

FIG. 2 schematically illustrates, in perspective, a step of manufacturing a quantum device, according to an embodiment of the present invention.

FIGS. 3A to 7A schematically illustrate, in a transverse cross-section, steps of manufacturing a quantum device, according to the first embodiment of the present invention.

FIGS. 3B to 7B schematically illustrates, in a transverse cross-section, steps of manufacturing a quantum device, according to the variant of the first embodiment of the present invention.

FIGS. 8, 9, 10 schematically illustrate, in perspective, steps of manufacturing a quantum device, according to an embodiment of the present invention.

FIGS. 11A, 11B, 11C, 11D schematically illustrate, in perspective, cross-sections of the quantum device illustrated in FIG. 10, according to an embodiment of the present invention.

FIGS. 12 to 19 schematically illustrate, in perspective, steps of manufacturing a quantum device, according to a second embodiment of the present invention.

FIGS. 20A, 20B schematically illustrate, in perspective, cross-sections of the quantum device illustrated in FIG. 19, according to a second embodiment of the present invention.

The drawings are given as examples and are not limiting of the invention. They constitute principle schematic representations intended to facilitate the understanding of the invention and are not necessarily to the scale of practical applications. In particular, on the principle diagrams, the thicknesses and/or the dimensions of the different layers, patterns and raised elements are not representative of reality. For reasons of clarity, all of the alphanumeric references are not systematically repeated from one figure to another. It is understood that the elements already described and referenced, when they are reproduced in another figure, typically have the same alphanumeric references, even if these are not explicitly mentioned. A person skilled in the art will identify, without difficulties, one same element reproduced in different figures.

### DETAILED DESCRIPTION

Before starting a detailed review of embodiments of the invention, optional features are stated below, which can optionally be used in association or alternatively:

According to an example, each transverse gate is superposed to the pair of first QD gates, along the direction z.

According to an example, the first QD gates partially cover the active zone. This improves the electrostatic control of the QDs.

According to an alternative example, the first QD gates do not cover the active zone.

According to an example, each transverse gate has a dimension by width, substantially equal to the dimensions by width of the first QD gates of the pair of first QD gates that said transverse gate surmounts, the dimensions by width of the transverse gate and of the first QD gates being taken along the longitudinal direction. The transverse gates are substantially superposed over at least some of the length of the first QD gates, along the transverse direction. The dimensional control between first QD gates and transverse gates is improved. This enables a more precise electrostatic control. The transverse tunnel barriers can be controlled with a greater precision.

According to an example, the device further comprises second QD gates inserted between the first QD gates along the longitudinal direction y, such that two second QD gates disposed opposite one another on either side of the active zone form a pair of second QD gates.

According to an example, the second QD gates do not cover the active zone.

According to an example, the device further comprises so-called longitudinal control gates extend mainly along the transverse direction, each longitudinal gate being inserted between a first transverse gate surmounting a first pair of first QD gates, and a second transverse gate surmounting a second pair of first QD gates. Each longitudinal gate is disposed on a pair of second QD gates, and separated from said second QD gates, transverse gates and from the active zone by a second gate dielectric. Each longitudinal gate is configured to control a longitudinal and/or diagonal tunnel barrier between the first QD gates of the first pair of QD gates and the first QD gates of the second pair of QD gates. The first QD gates and the second QD gates are typically alternated along the longitudinal direction. The longitudinal gates are disposed on the second pairs of QD gates, typically at a “second stage” of gates. The longitudinal gates of this second stage control, in particular, the diagonal tunnel barriers between the first pairs of QD gates. The second pairs of QD gates, at the “first stage” of gates, control, in particular, the longitudinal tunnel barriers between the first pairs of QD gates.

According to an example, the transverse gates and the longitudinal gates are disposed alternating along the active zone, i.e. along the longitudinal direction.

According to an example, each longitudinal gate surmounts a pair of second QD gates opposite one another and superposes said pair of second QD gates, along the direction z. According to an example, the number of first QD gates is equal to twice the number of transverse gates. According to an example, the number of pairs of first QD gates is equal to the number of transverse gates. According to an example, the number of second QD gates is equal to twice the number of longitudinal gates. According to an example, the number of pairs of second QD gates is equal to the number longitudinal gates.

According to an example, each longitudinal gate has a dimension by width substantially equal to the dimensions by width of the second QD gates of the pair of second QD gates that said longitudinal gate surmounts, the dimensions by width of the longitudinal gate and of the second QD gates being taken along the longitudinal direction. The dimensional control between second QD gates and longitudinal gates is improved. This enables a more precise electrostatic control. The longitudinal tunnel barriers can be controlled with a greater precision. The longitudinal gates are substantially superposed on at least some of the length of the second QD gates, along the transverse direction.

According to an example, the transverse gates each have a first dimension by width and the longitudinal gates each have a second dimension by width, said first and second dimensions by width being taken along the longitudinal direction, and the second dimension by width is different from the first dimension by width. For example, the second dimension by width is strictly greater than the first dimension by width, or vice versa.

According to an example, the first and second gate dielectrics respectively have first and second thicknesses along the direction z, and the second thickness is different from the first thickness. For example, the second thickness is strictly greater than the first thickness, or vice versa.

According to an example, each transverse gate has a portion, typically a central portion, relatively thicker, projecting in the direction of the active zone, such that said portion is close to the active zone.

According to an example, each transverse gate has a length less than the sum of the lengths of the first QD gates that it covers, the lengths being taken along the transvers direction x.

According to an example, the transverse gates are shorter than the pairs of first QD gates, along the transverse direction. The transverse gates are typically disposed in steps on the pairs of first QD gates. Thus, a part of each first QD gate forming the pair of first QD gates is not covered by the transverse gate. This makes it possible to form an electrical contact with the first QD gates by a through via, in vertical alignment with each first QD gate.

According to an example, the device further comprises at least one charge reservoir connected to the active zone, said charges being intended to supply the quantum dots of the device. According to an example, the device comprises at least two charge reservoirs, disposed on either side of the active zone.

According to an example, the longitudinal gates are shorter than the pairs of second QD gates, along the transverse direction. The longitudinal gates are typically disposed in steps on the pairs of second QD gates. Thus, a part of each second QD gate forming the pair of second QD gates is not covered by the longitudinal gate. This makes it possible to form an electrical contact with the second QD gates by a through via, in vertical alignment with each second QD gate.

According to an example, the longitudinal gates do not cover the active zone.

According to an example, the first lithography mask surmounts a layer with the basis of a high dielectric constant material. According to an example, the first lithography mask is SiN-based.

According to an example, before the deposition of the first gate layer, the first lithography mask is partially etched, selectively at the layer with the basis of the high dielectric constant material, so as to expose parts of the layer with the high dielectric constant material above the active zone, such that the first QD gates formed from the first gate layer partially cover the active zone.

According to an example, the method further comprises, after formation of the transverse gates surmounting the pairs of first QD gates,
A deposition of a second dielectric barrier covering exposed flanks of the first QD gates and transverse gates,
A deposition of a third gate layer on either side of the active zone, between the first QD gates, said third gate layer being intended to form second QD gates on either side of the active zone,
A deposition of a second dielectric material on the third gate layer, intended to form a second gate dielectric,
A deposition of a fourth gate layer on the second dielectric material, between the transverse gates, said fourth gate layer being intended to form longitudinal gates, each longitudinal gate being disposed on a pair of second QD gates opposite one another, on either side of the active zone, the longitudinal gates being self-aligned with the pairs of second QD gates that they surmount.

Advantageously, the method makes it possible to form transverse gates on pairs of first QD gates, in a self-aligned manner, and longitudinal gates on pairs of second QD gates, also in a self-aligned manner. This makes it possible to obtain an excellent dimensional control between the different gate types. The electrostatic control of the quantum device is improved.

According to an example, the method further comprises, after formation of the transverse gates and/or longitudinal gates:
A formation of a third lithography mask comprising openings in vertical alignment with the transverse gates and/or the longitudinal gates on the side of an end of the first QD gates and/or second QD gates opposite the active zone,
A partial removal of the transverse gates and/or longitudinal gates through said openings, so as to expose a part of the first QD gates and/or of the second QD gates.

This makes it possible to form the transverse gates and/or the longitudinal gates in steps on the first QD gates and/or the second QD gates, respectively. The electrical reconnection on the first QD gates and/or the second QD gates is facilitated. Typically, through vias are formed in vertical alignment with the first QD gates and/or the second QD gates.

Unless incompatible, it is understood that all of the optional features above can be combined, so as to form an embodiment which is not necessarily illustrated or described. Such an embodiment is clearly not excluded from the invention. The features and the advantages of an aspect of the invention, for example, the device or the method, can be adapted mutatis mutandis to the other aspect of the invention.

The invention generally relates to a quantum device comprising a plurality of transverse gates, and to a method for manufacturing such a device. The multiplicity of transverse gates makes it possible to locally control transverse quantum barriers between two QD gates of a pair of QD gates opposite one another. Controlling the coupling by tunnel effect between QD gates along the transverse direction is thus done “individually”, and not collectively as is the case in known devices. The options of controlling the device are increased. Preferably, the device also comprises a plurality of longitudinal gates. The multiplicity of longitudinal gates makes it possible to locally control longitudinal quantum barriers between different pairs of adjacent QD gates. Controlling the coupling by tunnel effect between QD gates along the longitudinal direction is also done “individually”. The device according to the invention, which typically has a quantum dot bilinear array architecture, can therefore be controlled with more precision and in an improved manner.

In the quantum device, the distribution of charge carriers is localised at a quantum dot or a quantum box. Quantum boxes are typically formed through an electrostatic confinement (via the application of a voltage on the gates) and a structural confinement (in the thin topSi layer forming the active zone, typically).

The possible interfering couplings and capacities induced by the different gates are not an essential problem for the correct operation of the device. An aspect to consider is the distance separating a control gate of the semiconductor portion, where the quantum boxes are formed. The closer a gate is positioned to the surface of the semiconductor portion, the more the crystalline defects present at the interfaces and in the gate oxide will be shielded. This minimises the impact of charged crystalline defects on the potential and facilitates the correct operation of the device. The invention advantageously makes it possible to position the transverse control gates closest to the quantum boxes.

From the point of view of the method of the embodiment, the invention also advantageously enables a self-alignment of all the elements to one another. This enables a good control of the distances separating the different gates and the different elements. This further avoids resorting to additional lithography steps. It is therefore advantageous to maximise the coverage rate of the substrate by gates, with gates closest to the substrate, such as implemented according to the present invention.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer at least partially covers the second layer by being either directly in contact with it, or by being separated from it by at least one other layer or at least one other element.

By gates “opposite” gates aligned along the transverse direction, this means gates which are partially or totally aligned with one another.

By a substrate, a film, a layer “with the basis” of a material A, this means a substrate, a film, a layer comprising this material A only or this material A and optionally other materials, for example, doping elements or alloy elements.

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the embodiment of a part of the method and can designate a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method.

By “selective etching opposite” or “etching having a selectivity opposite” means an etching configured to remove a material A or a layer A opposite a material B or a layer B, and having an etching speed of the material A greater than the etching speed of the material B. The selectivity is the ratio between the etching speed of the material A over the etching speed of the material B. It is referenced SA: B. A selectivity SA: B of 10:1 means that the etching speed of the material A is 10 times greater than the etching speed of the material B.

A preferably orthonormal system, comprising the axes x, y, z is represented in the accompanying figures. When one single system is represented in one same set of figures, this system applies to all the figures of this set. The transverse direction is oriented along x. The longitudinal direction is oriented along y.

In the present patent application, preferably thickness will be referred to for a layer or a film, and height will be referred to for a device or a structure. The thickness is taken along a direction normal to the main extension plane of the layer or of the film. Thus, a superficial silicon (topSi) layer typically has a thickness along z. A gate pattern formed on such a superficial layer has a height along z. The relative terms “on”, “surmounts”, “under”, “underlying” refer to positions taken along the direction z.

An element located “in vertical alignment” or “to the right of” another element means that these two elements are both located on one same line perpendicular to a plane in which a lower or upper face of a substrate mainly extends, i.e. on one same line oriented vertically in the figures in a transverse cross-section.

The terms “substantially”, “around”, “about” mean plus or minus 10%, and preferably plus or minus 5%. Moreover, the terms “between . . . and . . . ” and equivalent mean that the limits are inclusive, unless mentioned otherwise.

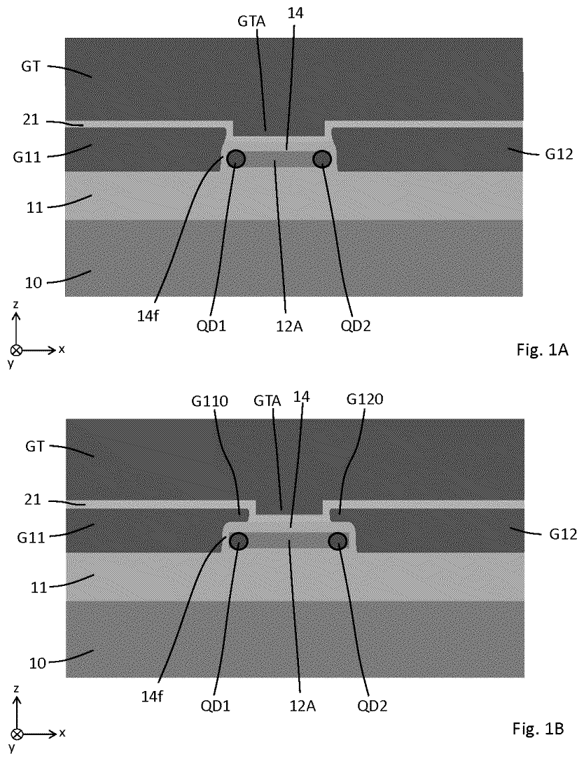

FIG. 1A schematically illustrates, in a transverse cross-section, a quantum device according to a first embodiment.

This device typically comprises a support part 10, typically a solid silicon substrate called “bulk”, an electrically insulating layer 11, typically a buried oxide layer called “BOX”, and an active zone 12A, for example, from a so-called topSi silicon layer. This stack can be formed from an SOI (silicon-on-insulator)-type substrate.

The active zone 12A is intended to accommodate quantum dots QD1, QD2, typically at the border of the active zone 12A. The active zone 12A typically has a thickness of about 5 nm to 20 nm. This makes it possible to structurally confine the quantum dots QD1, QD2, along z.

The device further comprises gates G11, G12 configured to confine and electrostatically control the quantum dots QD1, QD2, respectively. The gates G11, G12 are typically disposed opposite one another along x, on either side of the active zone 12A. They are separated from the active zone 12A by a dielectric barrier 14f.

The device further advantageously comprises a transverse gate GT covering the gates G11, G12, and the active zone 12A. The transverse gate GT is continuous along x. It typically has a portion GTA projecting in the proximity of the active zone 12A, separated from the active zone 12A by an oxide layer 14 and by the first dielectric 21. This portion GTA is typically located at the centre of the transverse gate GT along the direction x, substantially in vertical alignment with the active zone 12A. The first dielectric 21 also separates the transverse gate GT from the gates G11, G12.

By biasing the transverse gate GT, it is possible to form and control a so-called transverse tunnel barrier between the quantum dots QD1, QD2, within the active zone 12A. This makes it possible to avoid a coupling by tunnel effect occurring along x, between the quantum dots QD1, QD2.

According to a variant illustrated in FIG. 1B, the gates G11, G12 respectively have parts G110, G120 extending above the active zone 12A, and partially covering it. They are typically separated from the active zone 12A by the oxide layer 14. These parts G110, G120 enable, in particular, a better electrostatic control of the quantum dots QD1, QD2. According to this example, the transverse gate GT also comprises a projecting part close to the active zone 12A, between the gates G11, G12.

In FIGS. 1A, 1B, only a pair of gates G11, G12 and a transverse gate GT are illustrated. The device typically comprises a plurality of pairs of gates G11, G12 regularly distributed along the longitudinal direction y, and a plurality of transverse gates GT surmounting the pairs of gates G11, G12.

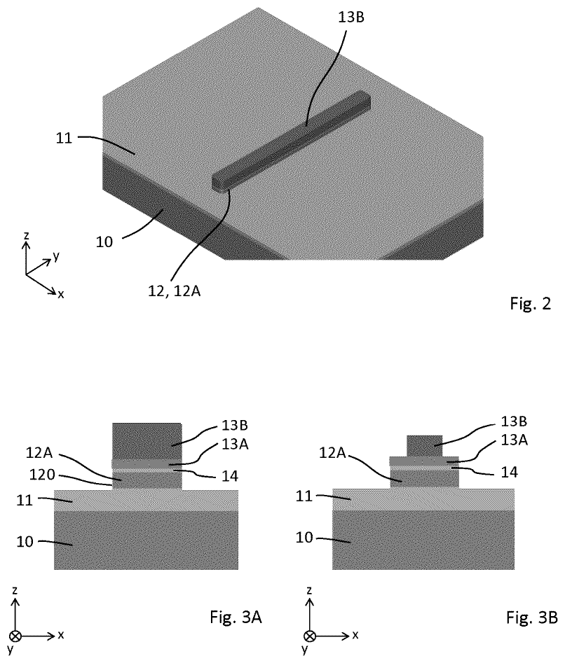

As illustrated in FIG. 2, after formation by lithography/etching a first etching mask 13B defining a pattern comprising the active zone 12A of the device, an anisotropic dry etching along z is carried out. The etching is stopped on the insulating layer 11 (BOX). A reactive ion etching (RIE) or a fluorocarbon species-based plasma etching can be used to etch the underlying layers of the stack, to the BOX.

FIGS. 3A, 3B illustrate two variants of formation of the first etching mask 13B, making it possible to ultimately produce the devices respectively illustrated in FIGS. 1A, 1B. Preferably, before formation of the first hard mask 13B and before etching of the layer 12, a thermal oxidation is performed on the surface of the layer 12, so as to form the oxide layer 14. An (optional) layer 13A with the basis of a high dielectric constant material is then deposited. The first etching mask 13B is then formed by lithography/etching on the stack of the layers 12, 14, 13A. It can be SiN-based.

According to the embodiment illustrated in FIG. 3A, after etching of the layers 13A, 14 and 12 to form the active zone 12A, the first etching mask 13B is simply preserved.

According to the embodiment illustrated in FIG. 3B, after etching of the layers 13A, 14 and 12 to form the active zone 12A, the first etching mask 13B is partially etched. In particular, the first SiN-based etching mask 13B is etched isotropically, selectively at the underlying layers 12A, 13A and 14. This makes it possible to reduce the dimensions along x and along z of the first etching mask 13B.

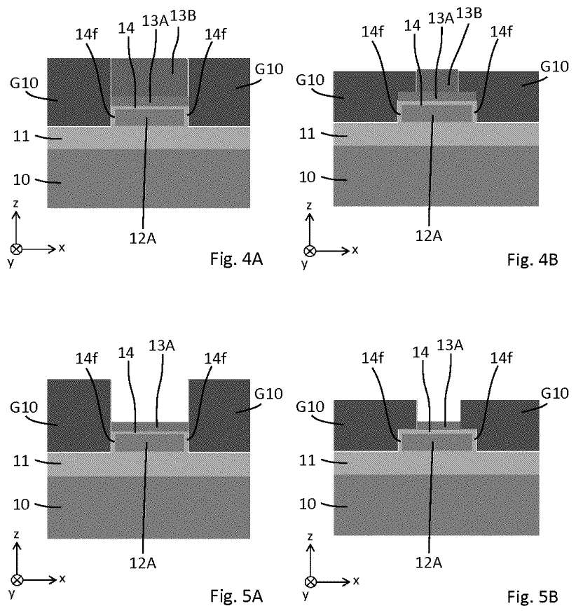

From the etching, the edges 120 of the active zone 12A are exposed. As illustrated in FIGS. 4A, 4B, a thermal oxidation is first performed, so as to form a first dielectric barrier 14f on each exposed edge 120 of the active zone 12A. A deposition of a first gate layer G10 is then performed on either side of the first etching mask 13B, for example, by chemical vapour deposition CVD. This deposition is typically conform and surmounts the first etching mask 13B. A planarisation step, typically by chemical-mechanical polishing CMP, is thus carried out. This planarisation step aims to remove the first gate layer G10 above the first etching mask 13B. The CMP is configured to stop on the first etching mask 13B. From the deposition and/or the planarisation, the first gate layer G10 is interrupted by the first etching mask 13B, along the transverse direction x. The first gate layer G10 is preferably polycrystalline silicon-based.

As illustrated in FIGS. 5A, 5B, after deposition and/or planarisation of the first gate layer G10, the first etching mask 13B is removed selectively at the layer 13A and at the first gate layer G10.

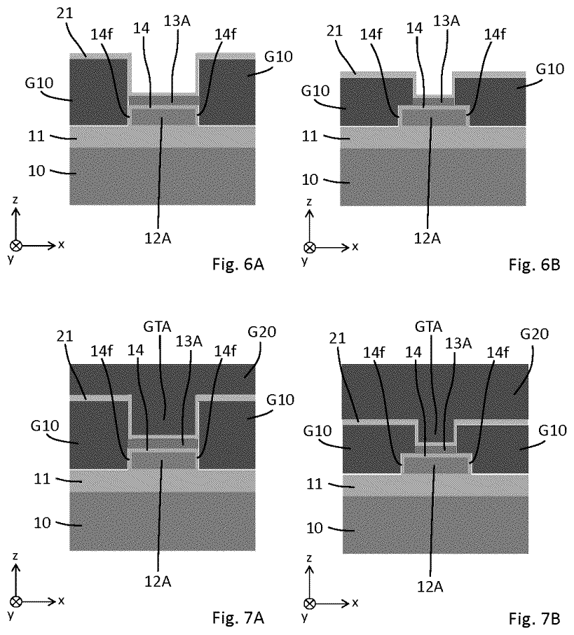

As illustrated in FIGS. 6A, 6B, the first gate dielectric 21 is formed by conform deposition of a continuous layer with the basis of a first dielectric material on the first gate layer G10 and on the layer 13A. The first gate dielectric 21 can have a thickness of about a few nanometres to a few tens of nanometres. It can be SiO₂-based.

As illustrated in FIGS. 7A, 7B, a deposition of a second gate layer G20 is then performed on the first gate dielectric 21. The cavity located above the active zone 12A is thus filled by the second gate layer G20. A CMP planarisation step is preferably also carried out. The second gate layer G20 is typically polycrystalline silicon-based.

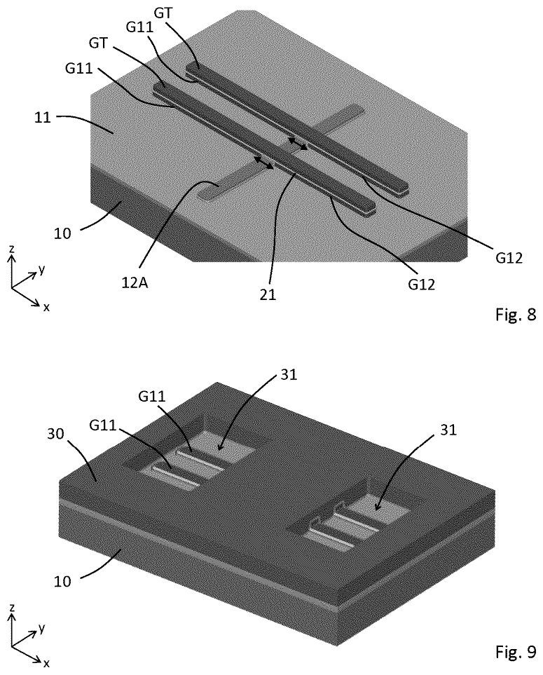

As illustrated in FIG. 8, the stack of the layers G10, 21, G20 is then structured conventionally by lithography and etching to form the gates G11, G12 and the superposed gates GT. The formation of the gates G11, G12 and of the gates GT is done advantageously by one same etching or series of etchings. This makes it possible to limit the number of lithography steps. This makes it possible to obtain the gates G11, G12 and the “self-aligned” gates GT, having substantially the same width along y. The dimension control is optimised. The electrostatic control via the gates G11, G12, GT is more precise.

The gates G11, G12 and the gates GT extend mainly along the direction x, transversely to the active zone 12A which extends mainly along the direction y. The gates GT superpose the gates G11, G12 and overlap the active zone 12A located between the gates G11, G12. The device advantageously comprises a plurality of gates GT making it possible to locally control a transverse tunnel barrier between the gates G11, G12 opposite one another.

According to an option, source and drain regions, or reservoirs for quantum devices, are formed at each end of the active zone 12A, for example, by epitaxy on either side of the active zone along x. These source and drain regions can be doped in situ during epitaxy. They can be phosphorus doped silicon Si:P-based, for example. The production of reservoirs and/or sources and drains is known to a person skilled in the art.

As illustrated in FIG. 9, a mask 30 comprising openings 31 is then formed on the gates GT. The openings 31 are located on either side of the active zone 12A, at the free ends of the gates G11, G12. Some of the gates GT are then etched through the openings 31, so as to expose the underlying gates G11, G12. This makes it possible to form stepped gates G11, G12 and GT. Making contact on the gates G11, G12 is thus facilitated.

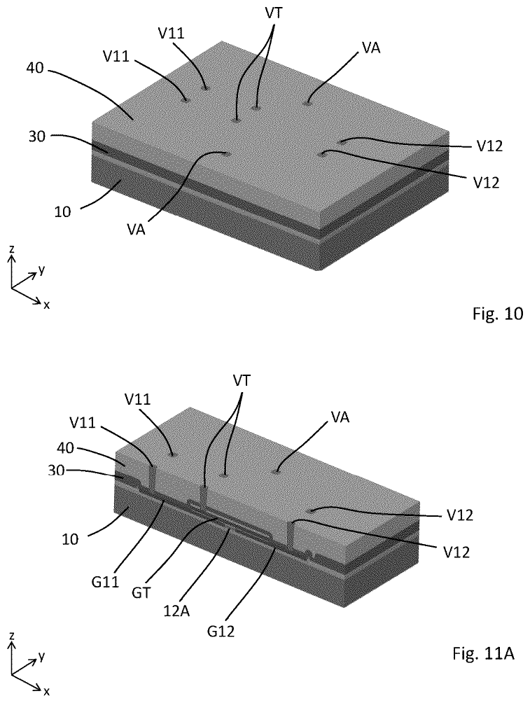

FIG. 10 illustrates the device after encapsulation by the encapsulation layer 40, and formation of the different electrical contacts. Vias V11 are formed in vertical alignment with the gates G11, on the parts of the gates G11 not covered by the gates GT. Vias VT are formed in vertical alignment with the gates GT. Vias VA are formed in vertical alignment with the active zone 12A, at each end along the direction y. Vias V12 are formed in vertical alignment with the gates G12, on the parts of the gates G12 not covered by the gates GT.

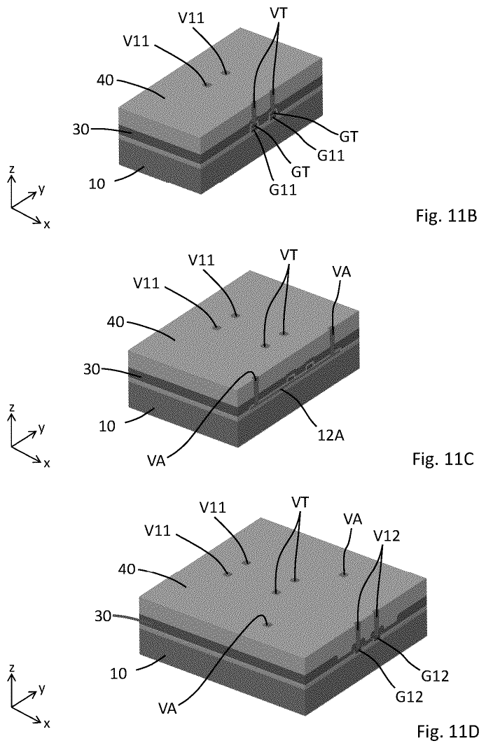

FIGS. 11A-11D have different transverse cross-sections, along the planes xz, and longitudinal, along the planes zy, of the device illustrated in FIG. 10. The stepped gates G11, G12 and GT, and the respective vias V11, V12 and VT can be seen (FIG. 11A, in particular). The vias VA contacting the active zone 12A can also be seen (FIG. 11C, in particular).

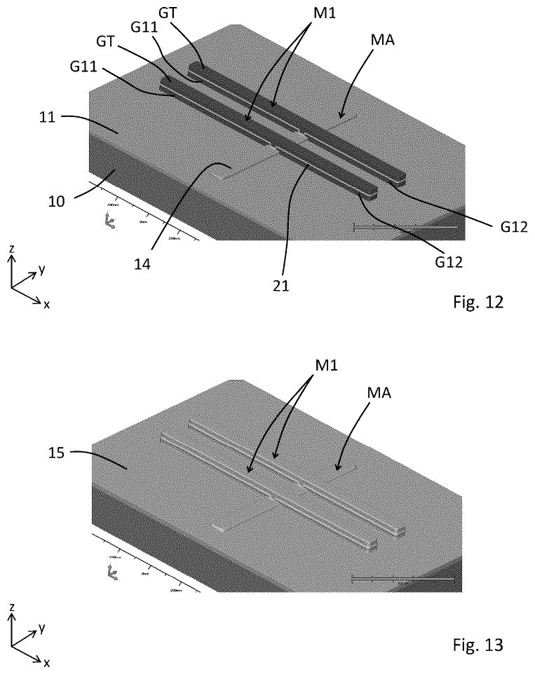

FIGS. 12 to 18A illustrate different steps of producing the device, according to a second embodiment. The steps illustrated in these FIGS. 12 to 18A are typically carried out after etching and definition of the gates G11, G12 and GT, such as illustrated in FIG. 8. They aim to form gates inserted between each set of superposed gates G11, G12, GT, along the longitudinal direction y. These additional inserted gates aim, in particular, to control the coupling by tunnel effect between gates G11, and/or between gates G12, and/or between gates GT, along the longitudinal direction y.

As illustrated in FIG. 12, the oxide layer 14 is preserved or reformed on the active zone 12A. The gate patterns M1 comprising the gates G11, G12, GT extend along x. The pattern MA comprising the active zone 12A extends along y.

As illustrated in FIG. 13, an oxide layer 15 is deposited to form a dielectric barrier on the exposed parts of the gates G11, G12, GT, in particular on the flanks of the gates G11, G12, GT and on the apexes of the gates GT.

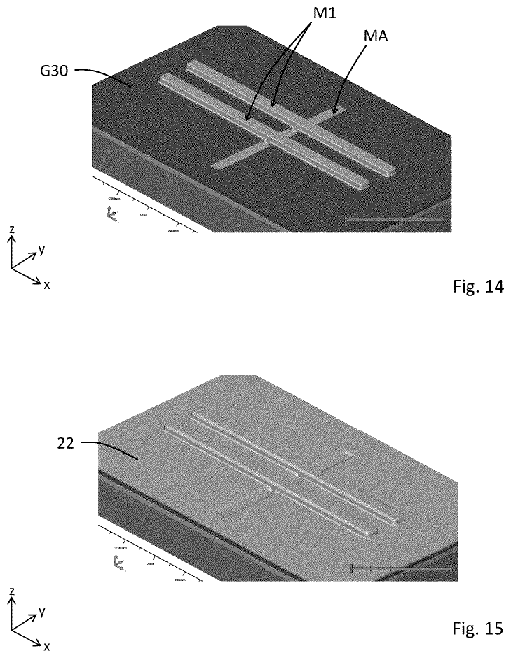

As illustrated in FIG. 14, a deposition of a third gate layer G30 is then performed on the oxide layer 15. In order to strip the patterns M1, MA, a CMP planarisation step can first be carried out. A partial etching of the third gate layer G30 can also be carried out. The third gate layer G30 can be polycrystalline silicon-based. Optionally, an epitaxial regrowth can be performed following the partial etching, so as to adjust the coverage of the edges of the active zone 12A by the third gate layer G30. From these steps, the third gate layer G30 is interrupted by the patterns M1, MA, which are partially exposed.

As illustrated in FIG. 15, the second gate dielectric 22 is formed by conform deposition of a continuous layer with the basis of a second dielectric material on the third gate layer G30 and on the patterns M1, MA.

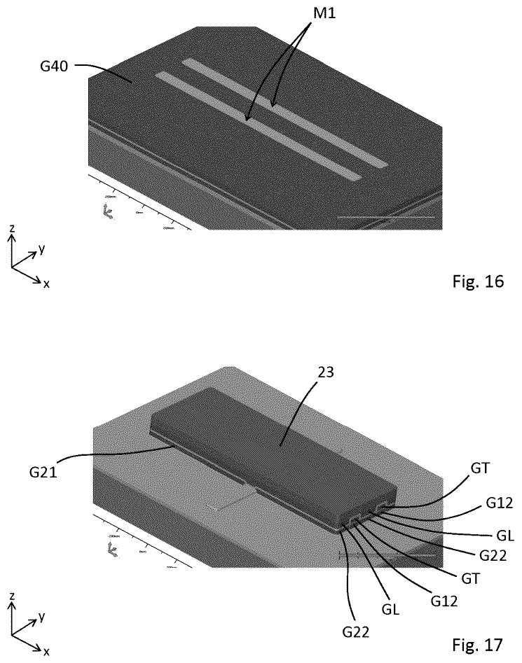

As illustrated in FIG. 16, a deposition of a fourth gate layer G40 is then performed on the second gate dielectric 22. The fourth gate layer G40 is typically polycrystalline silicon-based. A CMP planarisation step is preferably carried out, in order to expose the apexes of the patterns M1. From these steps, the fourth gate layer G40 is interrupted by the patterns M1.

As illustrated in FIG. 17, the stack of the layers G40, 22, G30 is then structured conventionally by lithography and etching to form the gates G21, G22 and the superposed gates GL. The gates G21, G22, GL are advantageously formed between the gates G11, G12, GT, along the direction y. The gate pitch along y can thus be divided by two.

The formation of the gates G21, G22 and of the gates GL is done advantageously by one same etching or series of etchings, around the mask 23. This makes it possible to limit the number of lithography steps. This makes it possible to obtain the gates G21, G22 and the “self-aligned” gates GL, having substantially the same width along y. The dimensional control is optimised. The electrostatic control via the gates G21, G22, GL is more precise.

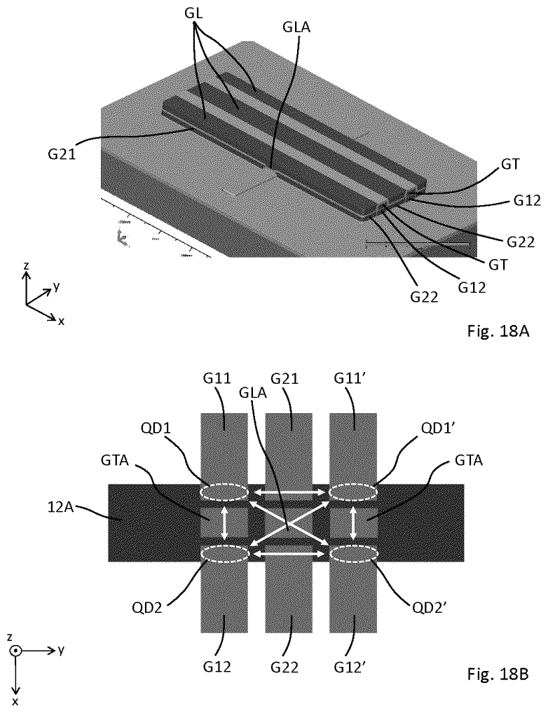

The device obtained after removal of the mask 23 is illustrated in FIG. 18A. The gates G21, G22, GL do not necessarily have the same width along y as the gates G11, G12, GT. The heights along z of the different gates G11, G12, GT, G21, G22, GL are not necessarily identical. The relative positioning along z of the gates G11, G12, GT and of the gates G21, G22, GL can vary. The thicknesses of the first and second gate dielectrics 21, 22 are not necessarily identical. Typically, the sum of the thicknesses of the gates or layers G12, 21, GT, 15, 22 is equal to the sum of the thicknesses of the gates or layers 15, G22, 22, GL.

Each set of superposed gates G21, G22, GL extends mainly along the direction x, between two sets of superposed gates G11, G12, GT. The device advantageously comprises a plurality of gates GL making it possible to locally control a longitudinal and/or diagonal tunnel barrier between two adjacent sets of superposed gates G11, G12, GT. Similarly to the gates GT, the gates GL typically have a portion GLA projecting in the proximity of the active zone 12A, separated from the active zone 12A by the oxide layer 13 and by the second dielectric 22. This portion GLA is typically located at the centre of each transverse gate GL along the direction x, substantially in vertical alignment with the active zone 12A.

As illustrated in FIG. 18B, according to a particular operating option, the portions GTA of the transverse gates GT control transverse tunnel barriers (represented by vertical arrows in FIG. 18B) between the first gates opposite one another, in this case between the gates G11 and G12 and between the gates G11′ and G12′. The second gates G21 and G22 control longitudinal tunnel barriers (represented by horizontal arrows in FIG. 18B) between the first gates side-by-side, in this case between the gates G11 and G11′ and between the gates G12 and G12′. The portion GLA of the longitudinal gate GL controls diagonal tunnel barriers (represented by diagonal arrows in FIG. 18B) between the first gates, in this case between the gates G11 and G12′ and between the gates G12 and G11′. The individual electrostatic control of the quantum dots QD1, QD2, QD1′, QD2′ is thus advantageously improved.

At this stage, source and drain regions and/or charge reservoirs can be formed at the ends of the active zone. The gates GL and GT are preferably structured in steps, as above. This structuration is done advantageously through one same mask, simultaneously for the gates GL and GT.

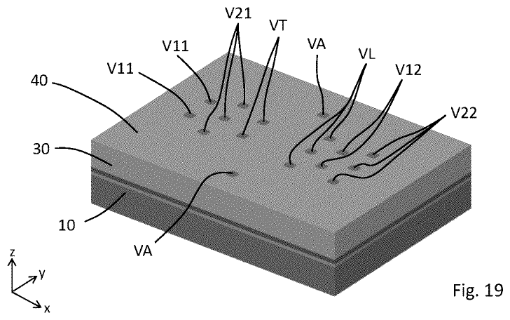

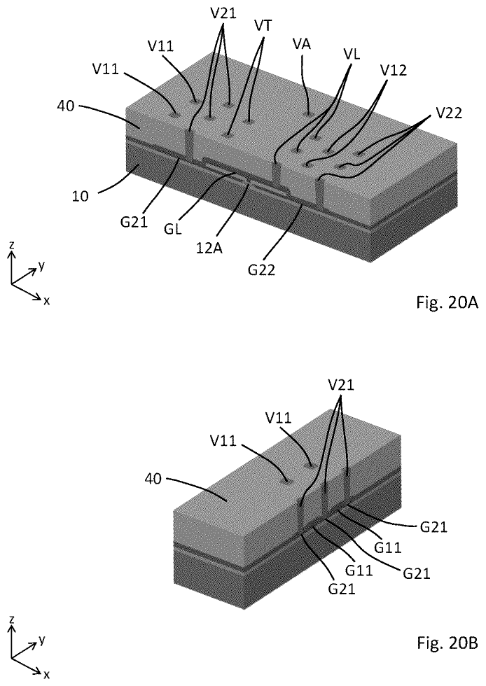

FIG. 19 illustrates the device after encapsulation by the encapsulation layer 40, and formation of the different electrical contacts. Vias V11 are formed in vertical alignment with the gates G11, on the parts of the gates G11 not covered by the gates GT, as above. Vias V21 are formed in vertical alignment with the gates G21, on the parts of the gates G21 not covered by the gates GL. Vias VT are formed in vertical alignment with the gates GT. Vias VA are formed in vertical alignment with the active zone 12A, at each end along the direction y. Vias VL are formed in vertical alignment with the gates G12, on the parts of the gates G12 not covered by the gates GT, as above. Vias V22 are formed in vertical alignment with the gates G22, on the parts of the gates G22 not covered by the gates GL.

FIGS. 20A, 20B have different transverse cross-sections, along the planes xz, and longitudinal, along the planes zy, of the device illustrated in FIG. 19. The stepped gates G21, G22 and GL, and the respective vias V21, V22 and VL can be seen (FIG. 20A). The alternance of the gates G11, G21 along y can also be seen (FIG. 20B).

In view of the description above, it clearly appears that the device and the method proposed offer a particularly effective and versatile solution to control the transverse and longitudinal tunnel coupling for a bilinear array quantum device. The invention is not limited to the embodiments described above. Other arrangements of quantum dots and/or tunnel barriers are possible, by taking advantage of the functionalisation of the different gates described in the above. The different gates are not necessarily perpendicular to the active zone. The second gates are not necessarily present. The gates GL can extend substantially over the entire height of the first gates and of the transverse gates. The gates GL can extend over the first and second stages of gates, for example.

1. A quantum device comprising successively, in a stack along a direction z,
a support layer,
an insulating layer, and
an active zone extending mainly along a so-called longitudinal direction,
the device further comprising:
first so-called QD control gates, extending mainly along a transverse direction with respect to the active zone, said first QD gates being disposed on either side of the active zone, opposite one another, each first QD gate being configured to control a potential well in the active zone, said potential well defining a quantum dot,
wherein the device further comprises:
a plurality of so-called transverse control gates, each extending mainly along the transverse direction, each transverse gate being disposed on two first QD gates opposite one another, forming a pair of first QD gates, and separated from said first QD gates and from the active zone by a first gate dielectric, each transverse gate being configured to control a transverse tunnel barrier between the quantum dots controlled by said pair of first QD gates.

2. The device according to claim 1, wherein the first QD gates do not cover the active zone.

3. The device according to claim 1, wherein each transverse gate has a dimension by width substantially equal to the dimensions by width of the first QD gates of the pair of first QD gates that said transverse gate surmounts, the dimensions by width of the transverse gate and of the first QD gates being taken along the longitudinal direction.

4. The device according to claim 1, wherein each transverse gate has a portion, relatively thicker, projecting in the direction of the active zone, such that said portion is close to the active zone.

5. The device according to claim 1, further comprising second QD gates inserted between the first QD gates along the longitudinal direction, such that two second QD gates disposed opposite one another on either side of the active zone form a pair of second QD gates.

6. The device according to claim 5, wherein the second QD gates do not cover the active zone.

7. The device according to claim 5, further comprising so-called longitudinal control gates extending mainly along the transverse direction, each longitudinal gate being inserted between a first transverse gate surmounting a first pair of first QD gates, and a second transverse gate surmounting a second pair of first QD gates, each longitudinal gate being disposed at least partially on a pair of second QD gates, and separated from said second QD gates, from the transverse gates and from the active zone by a second gate dielectric,
each longitudinal gate being configured to control a longitudinal and/or diagonal tunnel barrier between the first QD gates of the first pair and the first QD gates of the second pair.

8. The device according to claim 7, wherein the transverse gates and the longitudinal gates are disposed alternating along the active zone, i.e. along the longitudinal direction.

9. The device according to claim 7, wherein each longitudinal gate has a dimension by width substantially equal to the dimensions by width of the second QD gates of the pair of second QD gates that said longitudinal gate surmounts, the dimensions by width of the longitudinal gate and of the second QD gates being taken along the longitudinal direction.

10. The device according to claim 7, wherein the transverse gates each have a first dimension by width and the longitudinal gates each have a second dimension by width, said first and second dimensions by width being taken along the longitudinal direction, and wherein the second dimension by width is different from the first dimension by width.

11. The device according to claim 7, wherein the first and second gate dielectrics respectively have first and second thicknesses taken along the direction z, and wherein the second thickness is different from the first thickness.

12. The device according to claim 1, further comprising at least one charge reservoir connected to the active zone, said charges being intended to supply the quantum dots of the device.

13. A method for producing a quantum device according to claim 1, said method comprising:
a provision of a stack comprising, along the direction z, a support layer, an insulating layer and a semiconductive layer,
a formation of a first lithography mask on the semiconductive layer, configured to define the active zone in the semiconductive layer,
an etching of the semiconductive layer, configured to form the active zone, said etching exposing the edges of said active zone,
a formation of a first dielectric barrier on each exposed edge of the active zone,
a deposition of a first gate layer on either side of the first lithography mask, against the first dielectric barrier bordering the active zone, said first gate layer being interrupted by the first lithography mask and intended to form the first QD gates on either side of the active zone,
a removal of the first lithography mask,
a continuous deposition of a first dielectric material on the first gate layer and above the active zone, intended to form the first gate dielectric,
a deposition of a second gate layer on the first dielectric material, said second gate layer being intended to form the transverse gates,
a formation of a second lithography mask on the second gate layer, configured to define the transverse gates and pairs of first QD gates under the transverse gates,
an etching along the direction z of the second gate layer, of the first dielectric material, and of the first gate layer, so as to form the transverse gates, the first gate dielectric and the pairs of first QD gates under each transverse gate, the transverse gates being self-aligned with the pairs of first QD gates that they surmount.

14. The method according to claim 13, wherein the first lithography mask surmounts a layer with the basis of a high dielectric constant material, and wherein, before the deposition of the first gate layer, the first lithography mask is partially etched, selectively at the layer with the basis of the high dielectric constant material, so as to expose parts of the layer with the basis of the high dielectric constant material above the active zone, such that the first QD gates formed from the first gate layer partially cover the active zone.

15. The method according to claim 13, further comprising, after formation of the transverse gates surmounting the pairs of first QD gates,
a deposition of a second dielectric barrier covering exposed flanks of the first QD gates and of the transverse gates,
a deposition of a third gate layer on either side of the active zone, between the first QD gates, said third gate layer being intended to form second QD gates on either side of the active zone,
a deposition of a second dielectric material on the third gate layer, intended to form a second gate dielectric,
a deposition of a fourth gate layer on the second dielectric material, between the transverse gates, said fourth gate layer being intended to form longitudinal gates, each longitudinal gate being disposed on a pair of second QD gates opposite one another, on either side of the active zone, the longitudinal gates being self-aligned with the pairs of second QD gates that they surmount.
